(19) United States
(12) Patent Application Publication
(10) Pub. No.: US 2024/0088263 A1
(43) Pub. Date: Mar. 14, 2024

(54) MANUFACTURING METHOD OF INTEGRATED CIRCUIT DEVICE

(71) Applicant: SAMSUNG ELECTRONICS CO., LTD., Suwon-si (KR)

(72) Inventors: Sungwoon HWANG, Suwon-si (KR); Dongryul CHANG, Suwon-si (KR); Byoungchul PARK, Suwon-si (KR); Hyesoo PARK, Suwon-si (KR); Sungrey WI, Suwon-si (KR); Yunjoo LEE, Suwon-si (KR); Kwangil CHOI, Suwon-si (KR); Jaesang CHOI, Suwon-si (KR); Hayeong CHOI, Suwon-si (KR); Soonchoel HER, Suwon-si (KR)

(21) Appl. No.: 18/242,628

(22) Filed: Sep. 6, 2023

(30) Foreign Application Priority Data
Sep. 8, 2022 (KR) 10-2022-0114466

(51) Int. Cl. H01L 29/66; H01L 29/40

(52) U.S. Cl. CPC H01L 29/66545; H01L 29/401; H01L 29/66795

(57) ABSTRACT

A method of manufacturing an integrated circuit device includes forming a dummy gate insulating layer on first to third active regions of a substrate, forming first to third dummy gates on the first to third active regions, respectively, forming an inter-gate insulating layer covering the first to third dummy gates, forming a third gate space by removing the third dummy gate while the first and second dummy gates are covered, forming an extra gate insulating layer on the dummy gate insulating layer exposed to the third gate space, forming first and second gate spaces by removing the first and second dummy gates while the third dummy gate is covered, removing a first portion of the dummy gate insulating layer exposed to the first gate space while the second and third gate spaces are covered, and forming a gate insulating layer and a gate electrode in the gate spaces.

### CROSS-REFERENCE TO RELATED APPLICATION

This application is based on and claims priority under 35 U.S.C. § 119 to Korean Patent Application No. 10-2022-0114466, filed on Sep. 8, 2022, in the Korean Intellectual Property Office, the disclosure of which is incorporated by reference herein in its entirety.

### BACKGROUND

### 1. Field

Embodiments relate to a manufacturing method of an integrated circuit device, and more particularly, to a manufacturing method of an integrated circuit device including a metal gate.

### 2. Description of the Related Art

Demand for high integration of integrated circuit devices is increasing according to the trend of light, thin, short, and small electronic products. As integrated circuit devices are highly integrated and multifunctional, it is required to develop an integrated circuit device capable of optimizing performance of an integrated circuit device while forming a plurality of transistors having different threshold voltages within a relatively small device area.

### SUMMARY

According to an aspect of embodiments, there is provided a method of manufacturing an integrated circuit device including forming a dummy gate insulating layer on a first active region, a second active region, and a third active region of a substrate, forming a first dummy gate, a second dummy gate, and a third dummy gate on the first to third active regions of the substrate, respectively, forming an inter-gate insulating layer covering sidewalls of the first to third dummy gates on the substrate, forming a third gate space by removing the third dummy gate while the first and second dummy gates are covered by a first mask, forming an extra gate insulating layer on a third portion of the dummy gate insulating layer exposed to a bottom portion of the third gate space, forming a first gate space and a second gate space by removing the first dummy gate and the second dummy gate while the third dummy gate is covered by a second mask, removing a first portion of the dummy gate insulating layer exposed to a bottom portion of the first gate space while the second and third gate spaces are covered by a third mask, and sequentially forming a gate insulating layer and a gate electrode in the first to third gate spaces.

According to another aspect of embodiments, there is provided a method of manufacturing an integrated circuit device including forming a dummy gate insulating layer on a first active region, a second active region, and a third active region of a substrate, forming a first dummy gate, a second dummy gate, and a third dummy gate on the first to third active regions of the substrate, respectively, and an inter-gate insulating layer covering sidewalls of the first to third dummy gates on the substrate, forming a third gate space surrounded by the inter-gate insulating layer and having a bottom portion in which a third portion of the dummy gate insulating layer is disposed by removing the third dummy gate, forming an extra gate insulating layer on the third portion of the dummy gate insulating layer in the third gate space, forming a first gate space and a second gate space surrounded by the inter-gate insulating layer and having bottom portions in which first and second portions of the dummy gate insulating layer are respectively disposed by removing the first dummy gate and the second dummy gate, removing the first portion of the dummy gate insulating layer in the first gate space, forming a gate insulating layer in each of the first to third gate spaces, and forming a gate electrode in each of the first to third gate spaces.

According to yet another aspect of embodiments, there is provided a method of manufacturing an integrated circuit device including forming a dummy gate insulating layer on a first active region, a second active region, and a third active region of a substrate, forming a first dummy gate, a second dummy gate, and a third dummy gate, respectively, on the first to third active regions of the substrate, forming a pair of first spacers, a pair of second spacers, and a pair of third spacers on both sidewalls of the first to third dummy gates, respectively, forming an inter-gate insulating layer covering sidewalls of the pair of first spacers, the pair of second spacers, and the pair of third spacers on the substrate, forming a first mask covering the first and second dummy gates and not covering the third dummy gate, forming a third gate space defined between the pair of third spacers and having a bottom portion in which a third portion of the dummy gate insulating layer is disposed by removing the third dummy gate, forming an extra gate insulating layer on the third portion of the dummy gate insulating layer in the third gate space, forming a second mask covering the third gate space and not covering the first and second dummy gates, forming a first gate space defined between the pair of first spacers and having a bottom portion in which a first portion of the dummy gate insulating layer is disposed and forming a second gate space defined between the pair of second spacers and having a bottom portion in which a second portion of the dummy gate insulating layer is disposed by removing the first dummy gate and the second dummy gate, forming a third mask covering the second gate space and the third gate space and not covering the first gate space, removing the first portion of the dummy gate insulating layer in the first gate space, forming a gate insulating layer in each of the first to third gate spaces, and forming a gate electrode in each of the first to third gate spaces.

### BRIEF DESCRIPTION OF THE DRAWINGS

Features will become apparent to those of skill in the art by describing in detail exemplary embodiments with reference to the attached drawings, in which:

FIG. 1 is a layout diagram illustrating an integrated circuit device according to some embodiments;

FIG. 2 is a cross-sectional view taken along line A1-A1′ of FIG. 1;

FIG. 3 is an enlarged view of portions E1, E2, and E3 of FIG. 2;

FIG. 4 is a layout diagram illustrating an integrated circuit device according to some embodiments;

FIG. 5 is a cross-sectional view taken along line A1-A1′ of FIG. 4;

FIG. 6 is a cross-sectional view taken along lines B1-B1′, B2-B2′, and B3-B3′ of FIG. 4;

FIG. 7 is a cross-sectional view taken along lines C1-C1′, C2-C2′, and C3-C3′ of FIG. 4;

FIG. 8 is an enlarged view of portions E1, E2, and E3 of FIG. 5; and

FIGS. 9 to 21 are cross-sectional views illustrating stages in a manufacturing method of an integrated circuit device, according to some embodiments.

### DETAILED DESCRIPTION

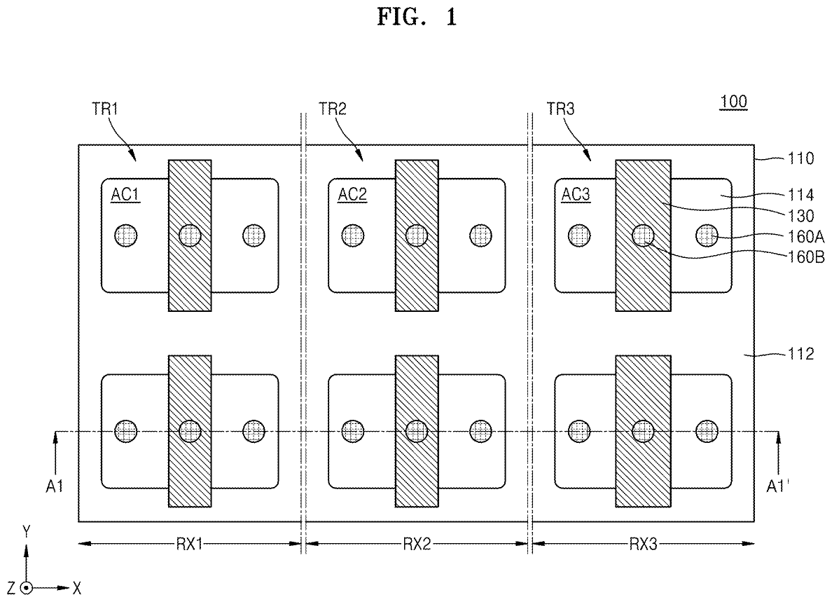

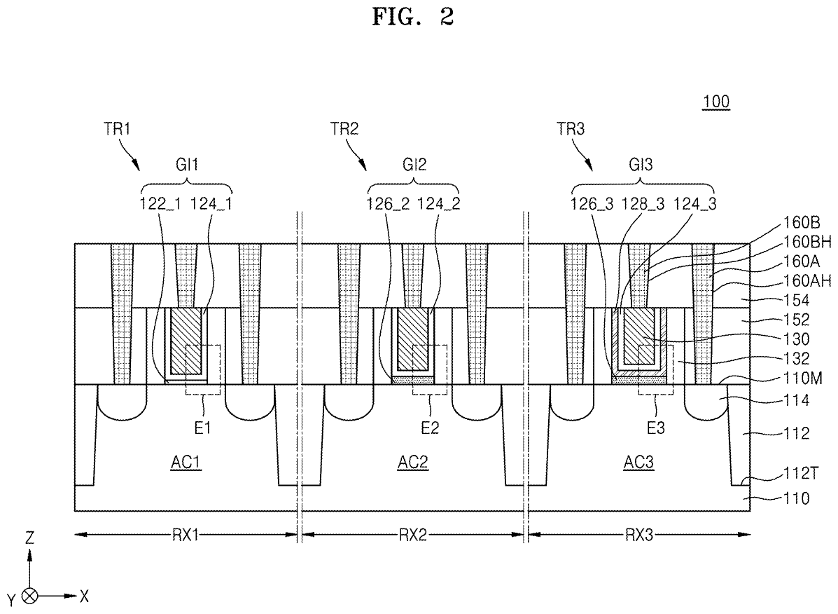

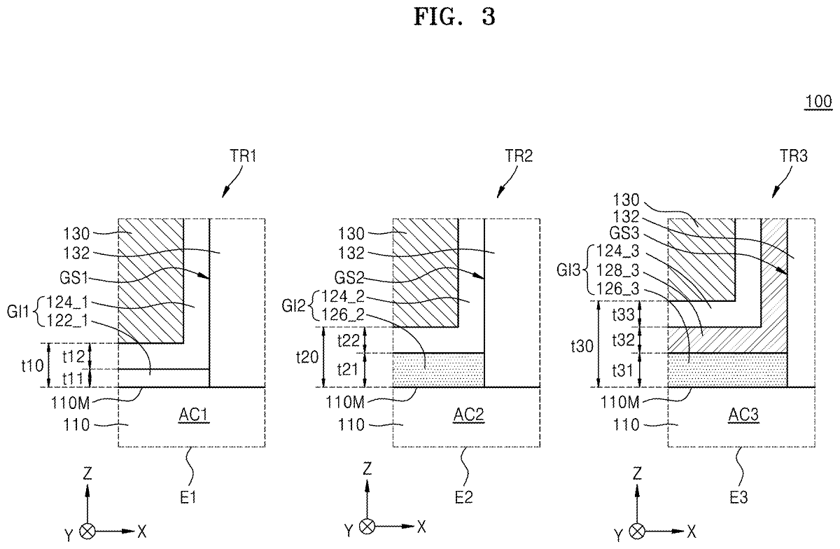

FIG. 1 is a layout diagram illustrating an integrated circuit device 100 according to some embodiments. FIG. 2 is a cross-sectional view taken along line A1-A1′ of FIG. 1. FIG. 3 is an enlarged view of portions E1, E2, and E3 of FIG. 2. In FIG. 1, some components of the integrated circuit device 100 are omitted for convenience of illustration.

Referring to FIGS. 1 to 3, a substrate 110 may include a first device region RX1, a second device region RX2, and a third device region RX3.

In some embodiments, a first transistor TR1 having a first threshold voltage may be disposed on the first device region RX1, a second transistor TR2 having a second threshold voltage may be disposed on the second device region RX2, and a third transistor TR3 having a third threshold voltage may be disposed on the third device region RX3. In some embodiments, the second threshold voltage may be greater than the first threshold voltage, and the third threshold voltage may be greater than each of the first threshold voltage and the second threshold voltage.

In some embodiments, the first transistor TR1 to which a first voltage is applied may be disposed on the first device region RX1, the second transistor TR2 to which a second voltage greater than the first voltage is applied may be disposed on the second device region RX2, and the third transistor TR3 to which a third voltage greater than the second voltage is applied may be disposed on the third device region RX3.

In some embodiments, the first device region RX1 may include a core region or a static random access memory (SRAM) device formation region, and may be, e.g., a region in which a standard cell performing a logical function is disposed. The standard cell may include various types of logic cells including a plurality of circuit devices, e.g., transistors and resistors. The logic cell may configure, e.g., an AND, a NAND, an OR, a NOR, an exclusive OR (XOR), an exclusive NOR (XNOR), an inverter (INV), an adder (ADD), a buffer (BUF), a delay (DLY), a filter (FIL), a multiplexer (MXT/MXIT), an OR/AND/INVERTER (OAI), an AND/OR (AO), an AND/OR/INVERTER (AOI), a D flip-flop, a reset flip-flop, a master-slave flip-flop, a latch, etc. In some embodiments, the second device region RX2 and the third device region RX3 may be regions in which an input/output circuit or an analog circuit is formed. However, the types of circuits formed in the first to third device regions RX1, RX2, and RX3 are not limited thereto.

The substrate 110 may include a Group IV semiconductor, e.g., Si or Ge, a Group IV-IV compound semiconductor, e.g., SiGe or SiC, or a Group III-V compound semiconductor, e.g., GaAs, InAs, or InP. In some embodiments, the substrate 110 may be a bulk substrate or may be a silicon-on-insulator (SOI)-type substrate. The substrate 110 may include a conductive region, e.g., a well doped with an impurity or a structure doped with an impurity.

A device isolation trench 112T may be formed in the substrate 110, and a device isolation layer 112 may be disposed in the device isolation trench 112T. A first active region AC1, a second active region AC2, and a third active region AC3 may be respectively defined in the first device region RX1, the second device region RX2, and the third device region RX3 of the substrate 110 by the device isolation layer 112.

The first transistor TR1 may include a first insulating structure GI1, a gate electrode 130, and a spacer 132 disposed on the first active region AC1, and an impurity region 114 disposed on the upper side of the first active region AC1. The second transistor TR2 may include a second insulating structure GI2, the gate electrode 130, and the spacer 132 disposed on the second active region AC2, and the impurity region 114 disposed on the upper side of the second active region AC2. The third transistor TR3 may include a third insulating structure GI3, the gate electrode 130, and the spacer 132 disposed on the third active region AC3, and the impurity region 114 disposed on the upper side of the third active region AC3. An inter-gate insulating layer 152 covering both, e.g., opposite, sidewalls of the spacer 132 may be disposed on the substrate 110.

In some embodiments, the first to third transistors TR1, TR2, and TR3 may respectively include the first to third insulating structures GI1, GI2, and GI3 having different thicknesses, and accordingly, the first to third transistors TR1, TR2, and TR3 may respectively have different first to third threshold voltages. For example, a thickness t10 of the first insulating structure GI1 may be in a range of about 3 angstroms to about 25 angstroms, a thickness t20 of the second insulating structure GI2 may be in a range of about 5 angstroms to about 80 angstroms, and a thickness t30 of the third insulating structure GI3 may be in a range of about 5 angstroms to about 200 angstroms.

A first gate space GS1 may be defined between a pair of spacers 132 on the first active region AC1, and the first insulating structure GI1 and the gate electrode 130 may be disposed in the first gate space GS1. Here, the pair of spacers 132 defining the first gate space GS1 may be referred to as a pair of first spacers. The first insulating structure GI1 may surround the bottom surface and sidewall of the gate electrode 130 and may be disposed between the pair of spacers 132 and the gate electrode 130. The first insulating structure GI1 may include a horizontal portion disposed between an upper surface 110M of the substrate 110 and the bottom surface of the gate electrode 130, and a vertical portion disposed on the sidewall of the gate electrode 130 and in contact with the sidewall of the spacer 132. In some embodiments, the first insulating structure GI1 may not be in direct contact with the inter-gate insulating layer 152. However, in some embodiments, the spacer 132 may be omitted, and in this case, the vertical portion of the first insulating structure GI1 may be disposed between the sidewall of the gate electrode 130 and the inter-gate insulating layer 152, and the vertical portion of the first insulating structure GI1 may be in direct contact with the inter-gate insulating layer 152 in the first gate space GS1.

The first insulating structure GI1 may include an interfacial layer 122_1 and a first portion 124_1 of a gate insulating layer sequentially stacked on the first active region AC1.

In some embodiments, the interfacial layer 122_1 may include silicon oxide, and may be formed by, e.g., a thermal oxidation process. A thickness t11 of the interfacial layer 122_1 may be in a range of about 1 angstroms to about 10 angstroms. The interfacial layer 122_1 may be disposed on the upper surface 110M of the substrate 110, and, e.g., may be included in the horizontal portion of the first insulating structure GI1 and may not be included in the vertical portion of the first insulating structure GI1. The first portion 124_1 of the gate insulating layer may be disposed on the interfacial layer 122_1. The first portion 124_1 of the gate insulating layer may be disposed between the interfacial layer 122_1 and the gate electrode 130 and between the spacer 132 and the gate electrode 130. The first portion 124_1 of the gate insulating layer may be included in both the horizontal portion and the vertical portion of the first insulating structure GI1.

In some embodiments, the first portion 124_1 of the gate insulating layer may include a high-k dielectric material. For example, the first portion 124_1 of the gate insulating layer may include a silicon oxynitride film, a silicon nitride film, a metal oxide, or a metal oxynitride, e.g., HfO₂, HfSiO, HfSiON, HfTaO, HfTiO, HfZrO, ZrO₂, Al₂O₃, or a combination thereof, but is not limited thereto. A thickness t12 of the first portion 124_1 of the gate insulating layer may be in a range of about 2 angstroms to about 20 angstroms.

The gate electrode 130 may be disposed in the first gate space GS1 on the first active region AC1. The gate electrode 130 may be disposed on the upper surface and the sidewall of the first insulating structure GI1 in the first gate space GS1, and may be in direct contact with, e.g., the first portion 124_1 of the gate insulating layer.

In some embodiments, the gate electrode 130 may include, e.g., a metal, a conductive metal nitride, a conductive metal carbide, a conductive metal silicide, or a combination thereof. For example, the gate electrode 130 may include Al, Cu, Ti, Ta, W, Mo, TaN, NiSi, CoSi, TiN, WN, TiAl, TiAlN, TaCN, TaC, TaSiN, or a combination thereof, but is not limited thereto. In some embodiments, the gate electrode 130 may include a work function metal-containing layer and a gap-fill metal layer. The work function metal-containing layer may include at least one metal of, e.g., Ti, W, Ru, Nb, Mo, Hf, Ni, Co, Pt, Yb, Tb, Dy, Er, or Pd. The gap-fill metal layer may be formed as, e.g., a W layer or an Al layer. In some embodiments, the gate electrode 130 may include, e.g., a stacked structure of TiAlC/TiN/W, a stacked structure of TiN/TaN/TiAlC/TiN/W, or a stacked structure of TiN/TaN/TiN/TiAlC/TiN/W, but is not limited thereto.

In some embodiments, the gate spacer 132 may include, e.g., silicon oxide (SiOₓ), silicon nitride (SiNₓ), silicon oxynitride (SiOₓN_{y}), silicon carbonitride (SiCₓN_{y}), silicon oxycarbonitride (SiOₓC_{y}N_{z}), or a combination thereof. In some embodiments, the gate spacer 132 may include a plurality of layers including different materials. In some embodiments, any one of the plurality of layers may include an air space.

A second gate space GS2 may be defined between the pair of spacers 132 on the second active region AC2, and the second insulating structure GI2 and the gate electrode 130 may be disposed in the second gate space GS2. The pair of spacers 132 defining the second gate space GS2 may be referred to as a pair of second spacers.

The second insulating structure GI2 may include a second portion 126_2 of a dummy gate insulating layer and a second portion 124_2 of the gate insulating layer sequentially stacked on the second active region AC2.

In some embodiments, the second portion 126_2 of the dummy gate insulating layer may include silicon oxide. A thickness t21 of the second portion 126_2 of the dummy gate insulating layer may be in a range of about 5 angstroms to about 60 angstroms. The second portion 126_2 of the dummy gate insulating layer may be disposed on the upper surface 110M of the substrate 110, and, e.g., may be included in the horizontal portion of the second insulating structure GI2 and may not be included in the vertical portion of the second insulating structure GI2.

The second portion 124_2 of the gate insulating layer may be disposed on the second portion 126_2 of the dummy gate insulating layer. The second portion 124_2 of the gate insulating layer may be disposed between the second portion 126_2 of the dummy gate insulating layer and the gate electrode 130 and between the spacer 132 and the gate electrode 130. The second portion 124_2 of the gate insulating layer may be included in both the horizontal portion and the vertical portion of the second insulating structure GI2.

In some embodiments, the second portion 124_2 of the gate insulating layer may include a high-k dielectric material. For example, the second portion 124_2 of the gate insulating layer may be a part of a material layer formed in the same process as that of the first portion 124_1 of the gate insulating layer. Accordingly, the second portion 124_2 of the gate insulating layer may include a material having the same composition as that of the first portion 124_1 of the gate insulating layer. A thickness t22 of the second portion 124_2 of the gate insulating layer may be in a range of about 2 angstroms to about 20 angstroms.

A third gate space GS3 may be defined between the pair of spacers 132 on the third active region AC3, and the third insulating structure GI3 and the gate electrode 130 may be disposed in the third gate space GS3. The pair of spacers 132 defining the third gate space GS3 may be referred to as a pair of third spacers.

The third insulating structure GI3 may include a third portion 126_3 of the dummy gate insulating layer, an extra gate insulating layer 128_3, and a third portion 124_3 of the gate insulating layer sequentially stacked on the third active region AC3.

In some embodiments, the third portion 126_3 of the dummy gate insulating layer may include silicon oxide. A thickness t31 of the third portion 126_3 of the dummy gate insulating layer may be in a range of about 5 angstroms to about 60 angstroms. The third portion 126_3 of the dummy gate insulating layer may be disposed on the upper surface 110M of the substrate 110, and, e.g., may be included in the horizontal portion of the third insulating structure GI3, and may not be included in the vertical portion of third insulating structure GI3.

For example, the third portion 126_3 of the dummy gate insulating layer may be a part of a material layer formed in the same process as that of the second portion 126_2 of the dummy gate insulating layer. Accordingly, the third portion 126_3 of the dummy gate insulating layer may include a material having the same composition as that of the second portion 126_2 of the dummy gate insulating layer.

In some embodiments, the extra gate insulating layer 128_3 may include silicon oxide or a high-k dielectric material. The extra gate insulating layer 128_3 may be disposed between the third portion 126_3 of the dummy gate insulating layer and the gate electrode 130 and between the spacer 132 and the gate electrode 130. The extra gate insulating layer 128_3 may be included in both the horizontal portion and the vertical portion of the third insulating structure GI3. A thickness t32 of the extra gate insulating layer 128_3 may be in a range of about 5 angstroms to about 120 angstroms.

The third portion 124_3 of the gate insulating layer may be disposed on the extra gate insulating layer 128_3. The third portion 124_3 of the gate insulating layer may be disposed between the extra gate insulating layer 128_3 and the gate electrode 130 and between the spacer 132 and the gate electrode 130. The third portion 124_3 of the gate insulating layer may be included in both the horizontal portion and the vertical portion of the third insulating structure GI3.

In some embodiments, the third portion 124_3 of the gate insulating layer may include a high-k dielectric material. For example, the third portion 124_3 of the gate insulating layer may be a part of a material layer formed in the same process as those of the first portion 124_1 of the gate insulating layer and the second portion 124_2 of the gate insulating layer. Accordingly, the third portion 124_3 of the gate insulating layer may include the material having the same composition as those of the first portion 124_1 of the gate insulating layer and the second portion 124_2 of the gate insulating layer. A thickness t33 of the third portion 124_3 of the gate insulating layer may be in a range of about 2 angstroms to about 20 angstroms.

The impurity region 114 may be a region formed by ion implantation of impurities into the upper side of each of the first to third active regions AC1, AC2, and AC3. For example, the impurity region 114 may function as a source/drain region of each of the first to third transistors TR1, TR2, and TR3.

An upper insulating layer 154 may be disposed on the inter-gate insulating layer 152. The inter-gate insulating layer 152 and the upper insulating layer 154 may include at least one of, e.g., silicon oxide, silicon carbon oxide, silicon oxynitride, or a low-k dielectric material.

A first contact 160A may be disposed in a first contact hole 160AH penetrating the upper insulating layer 154 and the inter-gate insulating layer 152 and exposing the upper surface of the impurity region 114. A second contact 160B may be disposed in a second contact hole 160BH penetrating the upper insulating layer 154 and exposing the upper surface of the gate electrode 130. The first contact 160A may be electrically connected to the impurity region 114, and the second contact 160B may be electrically connected to the gate electrode 130. The first contact 160A and the second contact 160B may include at least one of, e.g., ruthenium (Ru), titanium (Ti), titanium nitride (TiN), tantalum (Ta), tantalum nitride (TaN), tungsten (W), titanium silicon nitride (TiSiN), titanium silicide (TiSi), tungsten silicide (WSi), cobalt (Co), nickel (Ni), copper (Cu), or aluminum (Al). Although not shown, a metal silicide layer may be further formed between the bottom surface of the first contact 160A and the upper surface of the impurity region 114.

The first contact 160A may be disposed in the first contact hole 160AH penetrating the upper insulating layer 154. The first contact 160A may be electrically connected to the impurity region 114. A metal silicide layer may be further formed between the bottom surface of the first contact 160A and the upper surface of the impurity region 114.

A plurality of conductive vias, a plurality of wiring lines, and an interlayer insulating layer covering the plurality of conductive vias and the plurality of wiring lines may be further disposed on the upper insulating layer 154. For example, a power voltage or a ground voltage may be applied to the impurity region 114 from at least one of the plurality of wiring lines through the first contact 160A, and a gate voltage may be applied to the gate electrode 130 from at least one of the plurality of wiring lines through the second contact 160B.

According to a manufacturing method of the integrated circuit device 100 according to some embodiments, using a first mask, a second mask, and a third mask, the first insulating structure GI1 including the interfacial layer 122_1 and the first portion 124_1 of the gate insulating layer may be formed on the first active region AC1, the second insulating structure GI2 including the second portion 126_2 of the dummy gate insulating layer and the second portion 124_2 of the gate insulating layer may be formed on the second active region AC2, and the third insulating structure GI3 including the third portion 126_3 of the dummy gate insulating layer, the extra gate insulating layer 128_3, and the third portion 124_3 of the gate insulating layer may be formed on the third active region AC3. Such a method may minimize damage to the first to third active regions AC1, AC2, and AC3 and the second and third portions of 126_2 and 126_3 of the dummy gate insulating layers, and thus, the integrated circuit device 100 may have a plurality of threshold voltages while exhibiting optimized performance.

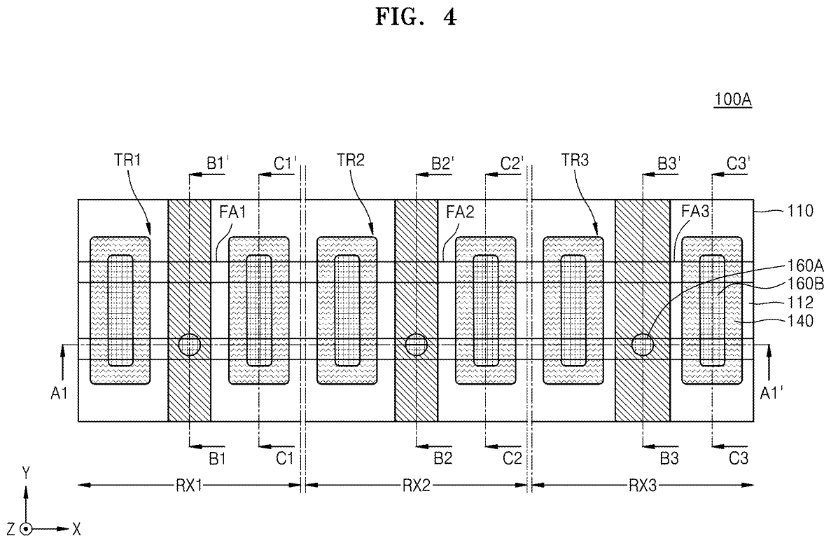

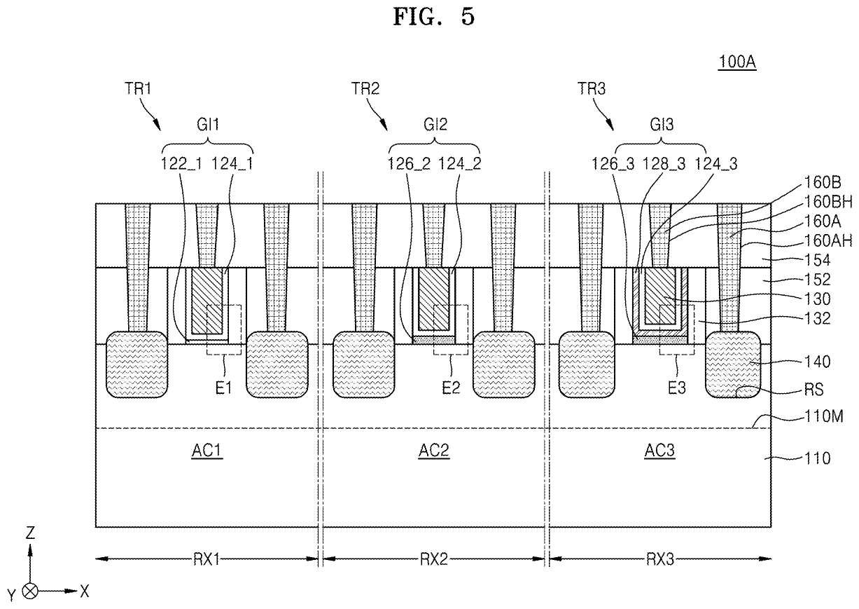

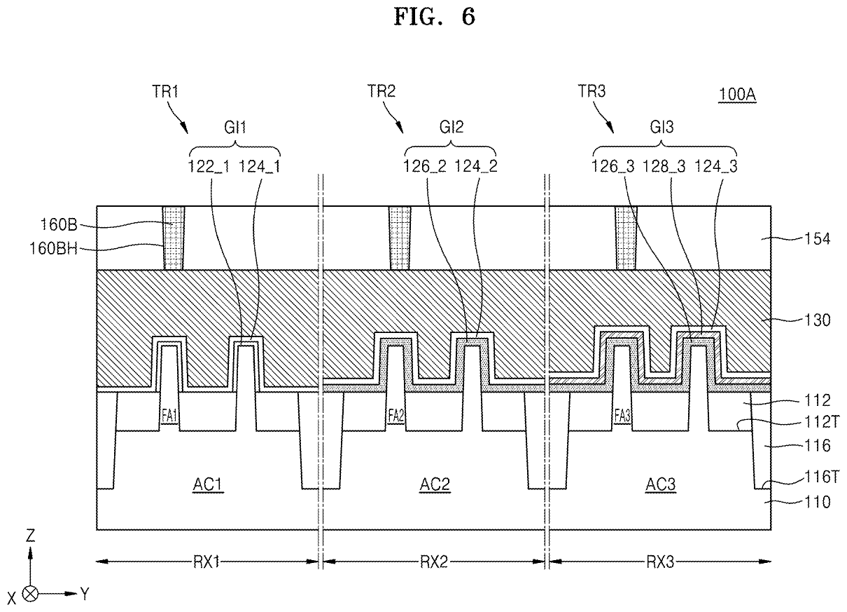

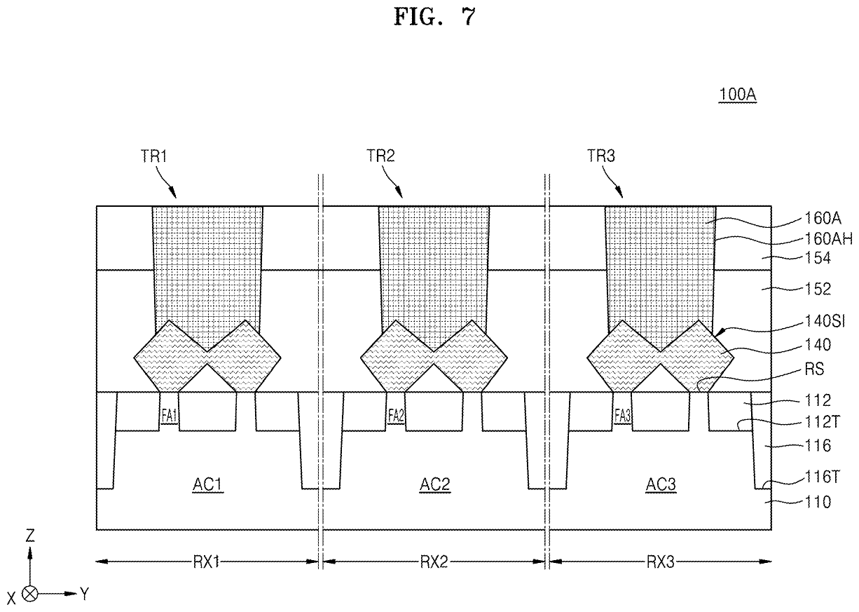

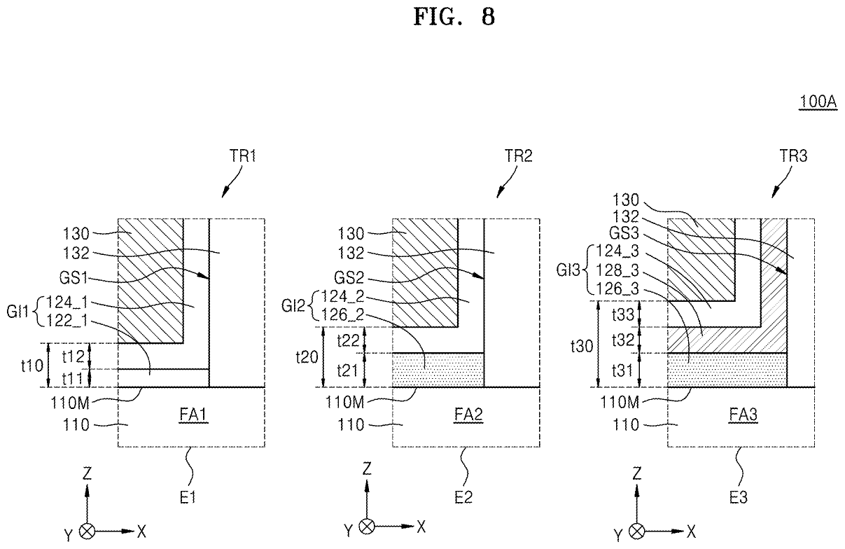

FIG. 4 is a layout diagram illustrating an integrated circuit device 100A according to some embodiments. FIG. 5 is a cross-sectional view taken along line A1-A1′ of FIG. 4. FIG. 6 is a cross-sectional view taken along lines B1-B1′, B2-B2′, and B3-B3′ of FIG. 4. FIG. 7 is a cross-sectional view taken along lines C1-C1′, C2-C2′, and C3-C3′ of FIG. 4. FIG. 8 is an enlarged view of portions E1, E2, and E3 of FIG. 5. In FIGS. 4 to 8, the same reference numerals as in FIGS. 1 to 3 denote the same components.

Referring to FIGS. 4 to 8, the first to third transistors TR1, TR2, and TR3 may be fin-type field effect transistors (finFETs). The substrate 110 may include a first fin-type active region FA1, a second fin-type active region FA2, and a third fin-type active region FA3 respectively on the first active region AC1, the second active region AC2, and the third active region AC3.

The first fin-type active region FA1 may protrude from the upper surface 110M of the substrate 110 on the first active region AC1, and may extend in a first direction (X direction). The second fin-type active region FA2 may protrude from the upper surface 110M of the substrate 110 on the second active region AC2, and may extend in the first direction (X direction). The third fin-type active region FA3 may protrude from the upper surface 110M of the substrate 110 on the third active region AC3, and may extend in the first direction (X direction).

Both sidewalls of the first fin-type active region FA1, both sidewalls of the second fin-type active region FA2, and both sidewalls of the third fin-type active region FA3 may be covered by the device isolation layer 112. For example, each of the first fin-type active region FA1, the second fin-type active region FA2, and the third fin-type active region FA3 may have an upper surface disposed at a vertical level spaced apart by about 5 nanometers to about 50 nanometers in a vertical direction Z from the upper surface of the device isolation layer 112, but is not limited thereto.

A deep trench 116T may be formed to a certain depth from the upper surface 110M of the substrate 110, and a deep trench insulating layer 116 may fill the inside of the deep trench 116T. The deep trench insulating layer 116 may have an upper surface disposed at the same level as the upper surface of the device isolation layer 112, and may have a bottom surface disposed at a lower level than the bottom surface of the device isolation layer 112.

Recess regions RS extending to the inside of the first fin-type active region FA1 may be formed on both sides of the gate electrode 130, and the impurity region 140 may be formed in each of the recess regions RS. Similarly, the recess regions RS extending to the inside of the second fin-type active region FA2 may be formed on both sides of the gate electrode 130, and the impurity region 140 may be formed in each of the recess regions RS. In addition, the recess regions RS extending to the inside of the third fin-type active region FA3 may be formed on both sides of the gate electrode 130, and the impurity region 140 may be formed in each of the recess regions RS. The impurity region 140 may function as a source/drain region of each of the first to third transistors TR1, TR2, and TR3.

In some embodiments, the impurity region 140 may include, e.g., a doped SiGe film, a doped Ge film, a doped SiC film, or a doped InGaAs film. For example, the impurity region 140 may be formed by removing a part of the first fin-type active region FA1 on both sides of the gate electrode 130 and the spacer 132, forming the recess region RS, and growing semiconductor layers filling the inside of the recess region RS by an epitaxial growth process, e.g., selective epitaxy. For example, as shown in FIG. 7, the impurity region 140 may have a plurality of inclined sidewalls 140SI.

In some embodiments, the impurity region 140 may include a plurality of semiconductor layers having different compositions from each other. For example, the impurity region 140 may include a lower semiconductor layer, an upper semiconductor layer, and a capping semiconductor layer sequentially filling the inside of the recess region RS. For example, the lower semiconductor layer, the upper semiconductor layer, and the capping semiconductor layer may each include SiC and have different contents of Si and C.

The first insulating structure GI1 may include the interfacial layer 122_1 and the first portion 124_1 of the gate insulating layer sequentially stacked on the first fin-type active region FA1. As shown in FIG. 6, the first insulating structure GI1 may cover the upper surface and both sidewalls of the first fin-type active region FA1 and may extend onto the upper surface of the device isolation layer 112. The interfacial layer 122_1 may be disposed on the upper surface and both sidewalls of the first fin-type active region FA1, and may not be disposed on the device isolation layer 112. The first portion 124_1 of the gate insulating layer may cover the upper surface and both sidewalls of the first fin-type active region FA1 on the interfacial layer 122_1 and extend onto the device isolation layer 112, and the bottom surface of the first portion 124_1 of the gate insulating layer may be in, e.g., direct, contact with the device isolation layer 112. The second insulating structure GI2 may include the second portion 126_2 of

the dummy gate insulating layer and the second portion 124_2 of the gate insulating layer sequentially stacked on the second fin-type active region FA2. As shown in FIG. 6, the second insulating structure GI2 may cover the upper surface and both sidewalls of the second fin-type active region FA2 and extend onto the upper surface of the device isolation layer 112. The second portion 126_2 of the dummy gate insulating layer may be disposed on the upper surface and both sidewalls of the second fin-type active region FA2 and may extend onto the device isolation layer 112, and the second portion 124_2 of the gate insulating layer may be conformally disposed on the second portion 126_2 of the dummy gate insulating layer.

The third insulating structure GI3 may include the third portion 126_3 of the dummy gate insulating layer, the extra gate insulating layer 128_3, and the third portion 124_3 of the gate insulating layer sequentially stacked on the third fin-type active region FA3. As shown in FIG. 6, the third insulating structure GI3 may cover the upper surface and both sidewalls of the third fin-type active region FA3 and extend onto the upper surface of the device isolation layer 112. The third portion 126_3 of the dummy gate insulating layer may be disposed on the upper surface and both sidewalls of the third fin-type active region FA3 and may extend onto the device isolation layer 112, and the extra gate insulating layer 128_3 and the third portion 124_3 of the gate insulating layer may be conformally disposed on the third portion 126_3 of the dummy gate insulating layer.

According to a manufacturing method of the integrated circuit device 100A according to some embodiments, using a first mask, a second mask, and a third mask, the first insulating structure GI1 including the interfacial layer 122_1 and the first portion 124_1 of the gate insulating layer may be formed on the first fin-type active region FA1, the second insulating structure GI2 including the second portion 126_2 of the dummy gate insulating layer and the second portion 124_2 of the gate insulating layer may be formed on the second fin-type active region FA2, and the third insulating structure GI3 including the third portion 126_3 of the dummy gate insulating layer, the extra gate insulating layer 128_3, and the third portion 124_3 of the gate insulating layer may be formed on the third fin-type active region FA3. Such a method may minimize damage to the first to third fin-type active regions FA1, FA2, and FA3 and the second and third portions of 126_2 and 126_3 of the dummy gate insulating layers, and thus, the integrated circuit device 100A may have a plurality of threshold voltages and optimized performance.

In other embodiments, the first and second fin-type active regions FA1 and FA2 may be respectively formed on the first active region AC1 and the second active region AC2, and the third fin-type active region FA3 may not be formed on the third active region AC3. In this case, the third transistor TR3 described with reference to FIGS. 1 to 3 may be formed on the third active region AC3.

In other embodiments, the substrate 110 may further include a fourth active region in addition to the first to third active regions AC1, AC2, and AC3, and a fourth transistor having a fourth threshold voltage different from first to third threshold voltages may be further formed on the fourth active region. The fourth transistor may include a fourth insulating structure having a thickness greater than that of each of the first to third insulating structures GI1, GI2, and GI3, and the fourth insulating structure may include one or more insulating layers including any one of silicon oxide, silicon nitride, silicon oxynitride, or a high-k dielectric material.

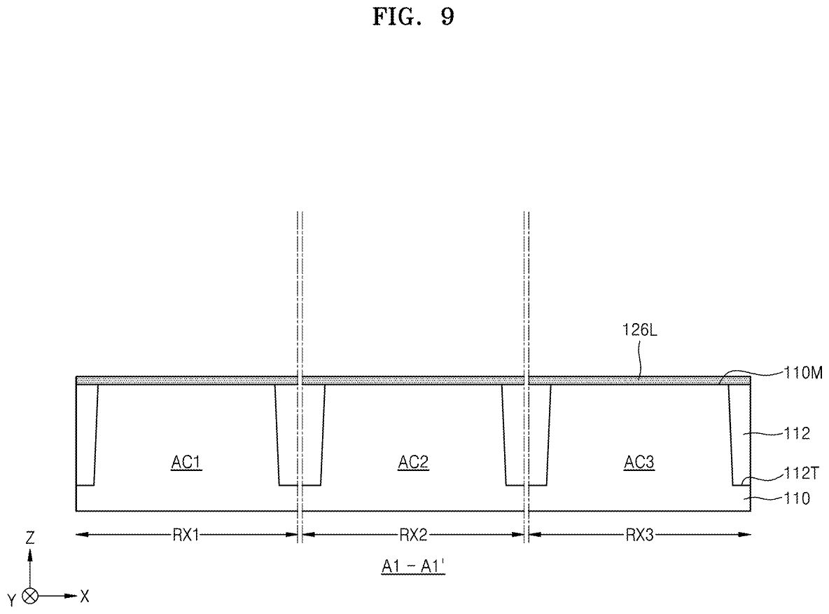

FIGS. 9 to 21 are cross-sectional views illustrating stages in a manufacturing method of the integrated circuit device 100, according to some embodiments. FIGS. 9 to 21 are cross-sectional views corresponding to the line A1-A1′ of FIG. 1. In FIGS. 9 to 21, the same reference numerals as in FIGS. 1 to 8 denote the same components.

Referring to FIG. 9, the isolation trench 112T is formed by forming a mask pattern on the upper surface of the substrate 110, and removing the substrate 110 by a certain thickness using the mask pattern as an etch mask. Thereafter, the device isolation layer 112 may be formed in the device isolation trench 112T to define the first active region AC1 in the first device region RX1, define the second active region AC2 in the second device region RX2, and define the third active region AC3 in the third device region RX3, e.g., each of the first through third active regions AC1 through AC3 may have a flat surface.

In some embodiments, the device isolation layer 112 may include an oxide layer formed by, e.g., a flowable chemical vapor deposition (FCVD) process or a spin coating process. For example, the device isolation layer 112 may include fluoride silicate glass (FSG), undoped silicate glass (USG), boro-phospho-silicate glass (BPSG), phospho-silicate glass (PSG), flowable oxide (FOX), plasma enhanced tetra-ethyl-ortho-silicate (PE-TEOS), or Tonen Silazene (TOSZ), but is not limited thereto.

Thereafter, a dummy gate insulating layer 126L may be formed on the substrate 110, e.g., the dummy gate insulating layer 126L may be formed continuously on the entire substrate 110 to cover each of the first active region AC1, the second active region AC2, and the third active region AC3. The dummy gate insulating layer 126L may be formed using silicon oxide by at least one of, e.g., an atomic layer deposition (ALD) process, a chemical vapor deposition (CVD) process, or a thermal oxidation process. In some embodiments, the dummy gate insulating layer 126L may be formed to a thickness of about 5 angstroms to about 60 angstroms.

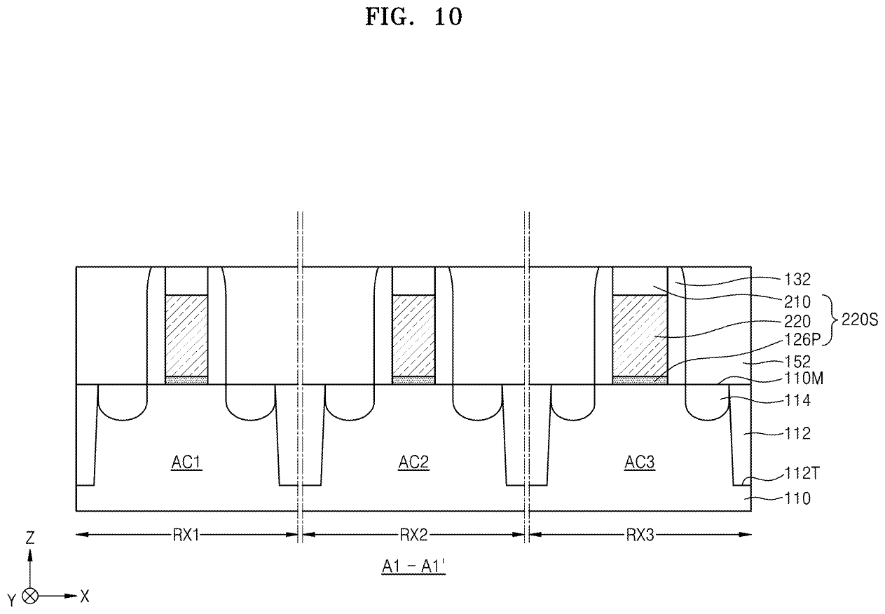

Referring to FIG. 10, a dummy gate 220 and a dummy gate insulating layer pattern 126P may be formed by forming a dummy gate conductive layer on the dummy gate insulating layer 126L, forming a hard mask pattern 210 on the dummy gate conductive layer, and patterning the dummy gate conductive layer and the dummy gate insulating layer 126L using the hard mask pattern 210 as an etch mask to form the dummy gate 220 and the dummy gate insulating layer pattern 126P, respectively. For example, the dummy gate 220 may be made of polysilicon.

Here, the dummy gate insulating layer pattern 126P, the dummy gate 220, and the hard mask pattern 210 may be sequentially stacked on each of the first to third active regions AC1, AC2, and AC3, and are referred to as a dummy gate structure 220S.

Thereafter, the spacer 132 may be formed on the sidewall of the dummy gate structure 220S by forming an insulating layer covering the dummy gate structure 220S using the ALD or the CVD process, and performing an anisotropic etching process on the insulating layer. The spacer 132 may include, e.g., silicon nitride.

Thereafter, the impurity region 114 may be formed by implanting impurity ions into the substrate 110 on both sides of the dummy gate structure 220S. The impurity region 114 may be formed by an ion implantation process to include n-type impurities or p-type impurities according to the type of a transistor to be formed on each of the first to third active regions AC1, AC2, and AC3.

Thereafter, the inter-gate insulating layer 152 may be formed by forming an insulating layer covering the dummy gate structure 220S on the substrate 110, and planarizing the insulating layer until the upper surface of the hard mask pattern 210 is exposed.

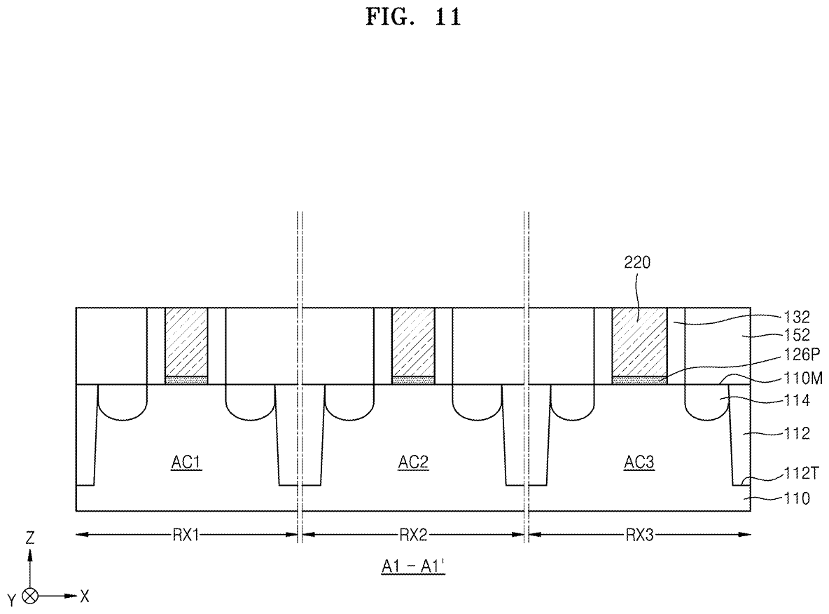

Referring to FIG. 11, the upper side portion of the inter-gate insulating layer 152 and the hard mask pattern 210 may be removed by performing a planarization process on the upper side of the inter-gate insulating layer 152 until the upper surface of the dummy gate 220 is exposed. Accordingly, the height of the inter-gate insulating layer 152 may be reduced, and the upper surface of the dummy gate 220 may be exposed.

As shown in FIG. 11, the dummy gate insulating pattern 260P and the dummy gate 220 may be sequentially disposed on the first active region AC1, a pair of spacers 132 may be disposed on both sides of the dummy gate 220, and the inter-gate insulating layer 152 may be disposed to surround sidewalls of the pair of spacers 132.

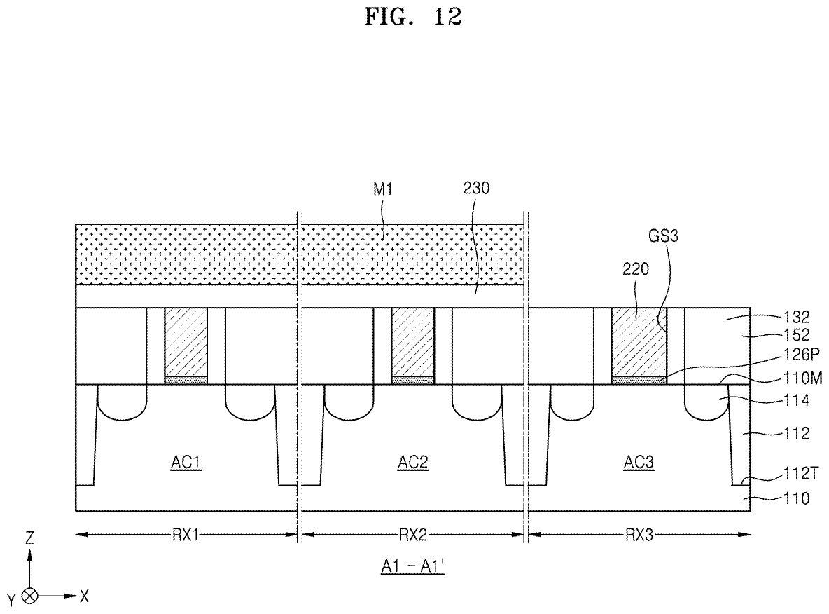

Referring to FIG. 12, a first cover insulating layer may be formed on the inter-gate insulating layer 152, and a first mask M1 covering the first active region AC1 and the second active region AC2 and not covering the third active region AC3 may be formed on the first cover insulating layer. For example, the first mask M1 may continuously cover the entireties of the first active region AC1 and the second active region AC2, while exposing the entirety of the third active region AC3. For example, the first mask M1 may be disposed to cover the dummy gate 220 disposed in the first active region AC1 and the dummy gate 220 disposed in the second active region AC2, and not to cover the dummy gate 220 disposed in the third active region AC3.

Thereafter, a first cover insulating pattern 230 may be formed by patterning the first cover insulating layer using the first mask M1. In some embodiments, the first cover insulating pattern 230 may be made of, e.g., silicon oxide, silicon oxynitride, or silicon nitride.

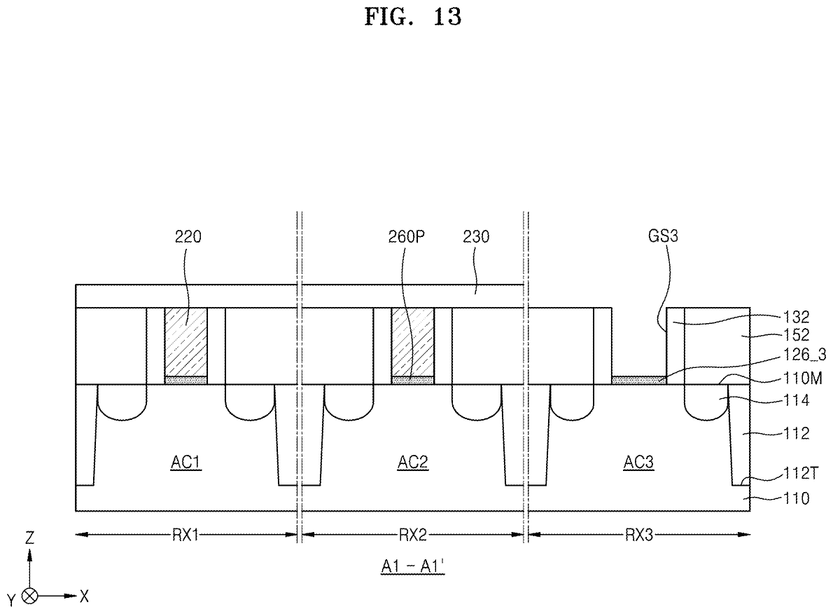

Referring to FIG. 13, while the dummy gate 220 disposed in the first active region AC1 and the dummy gate 220 disposed in the second active region AC2 are covered, the dummy gate 220 disposed in the third active region AC3 may be removed.

In some embodiments, the first mask M1 may be removed before a removing process of the dummy gate 220 in the third active region AC3, and the first cover insulating pattern 230 may cover the upper surface of the dummy gates 220 on the first and second active regions AC1 and AC2 during the removing process of the dummy gate 220 from the third active region AC3, so that the dummy gates 220 on the first and second active regions AC1 and AC2 are not exposed to an etching atmosphere.

In some other embodiments, the first mask M1 may be removed after the removing process of the dummy gate 220 from the third active region AC3, and the first cover insulating pattern 230 and the first mask M1 may cover the upper surface of the dummy gates 220 on the first and second active regions AC1 and AC2 during the removing process of the dummy gate 220 from the third active region AC3, so that the dummy gates 220 on the first and second active regions AC1 and AC2 are not exposed to the etching atmosphere.

After the removal process of the dummy gate 220 from the third active region AC3, a third gate space GS3 between the pair of spacers 132 may be formed on the third active region AC3. The dummy gate insulating layer pattern 126P may be exposed to the bottom portion of the third gate space GS3. The dummy gate insulating layer pattern 126P disposed on the bottom portion of the third gate space GS3 is referred to as the third portion 126_3 of the dummy gate insulating layer.

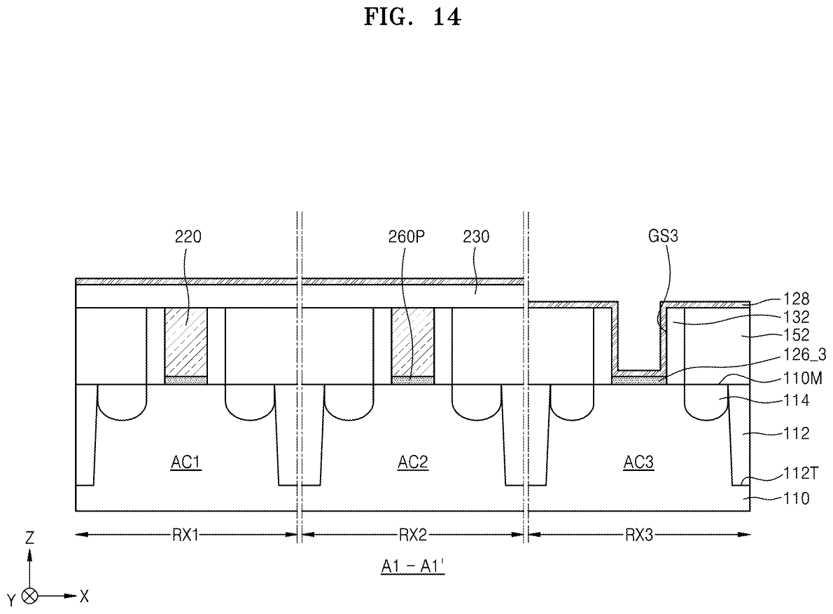

Referring to FIG. 14, the extra gate insulating layer 128 may be formed in the third gate space GS3. The extra gate insulating layer 128 may be conformally disposed on the inner wall of the third gate space GS3, and, e.g., may be formed on the sidewalls of the pair of spacers 132 in the third gate space GS3 and on the upper surface of the third portion 126_3 of the dummy gate insulating layer.

In some embodiments, the extra gate insulating layer 128 may be formed by, e.g., a CVD process or an ALD process using silicon oxide or a high-k dielectric material. In some embodiments, the extra gate insulating layer 128 may be formed to a thickness of about 5 angstroms to about 120 angstroms.

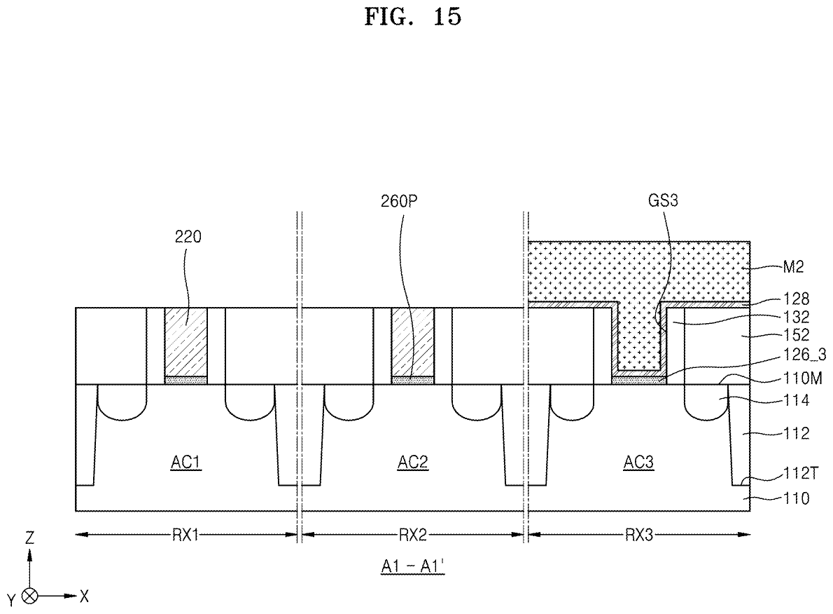

Referring to FIG. 15, a second mask M2 covering only the third active region AC3 and not covering the first active region AC1 and the second active region AC2 may be formed. For example, the second mask M2 may be disposed to cover portions of the third gate space GS3 and the extra gate insulating layer 128 disposed in the third active region AC3 and not to cover portions of the dummy gate 220 and the extra gate insulating layer 128 disposed in the first active region AC1 and portions of the dummy gate 220 and the extra gate insulating layer 128 disposed in the second active region AC2.

Thereafter, while the second mask M2 covers the third active region AC3, portions of the first cover insulating pattern 230 and the extra gate insulating layer 128 disposed on the first active region AC1 and the second active region AC2 may be removed. As portions of the first cover insulating pattern 230 and the extra gate insulating layer 128 are removed from the first active region AC1 and the second active region AC2, the upper surfaces of the dummy gates 220 and the upper surface of the inter-gate insulating layer 152 may be exposed again in the first active region AC1 and the second active region AC2.

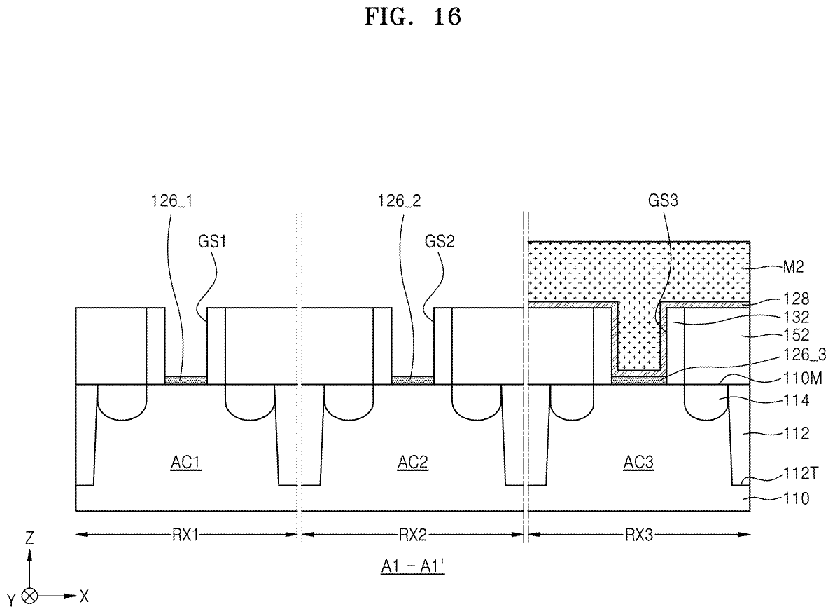

Referring to FIG. 16, while the second mask M2 covers the third active region AC3, the dummy gate 220 disposed in the first active region AC1 and the dummy gate 220 disposed in the second active region AC2 may be removed.

The dummy gate 220 disposed in the first active region AC1 may be removed, so that the first gate space GS1 may be formed, and the dummy gate 220 disposed in the second active region AC2 may be removed, so that the second gate space GS2 may be formed. The dummy gate insulating layer pattern 126P may be exposed to the bottom portions of the first gate space GS1 and the second gate space GS2. The dummy gate insulating layer pattern 126P disposed on the bottom portion of the first gate space GS1 is referred to as the first portion 126_1 of the dummy gate insulating layer, and dummy gate insulating layer pattern 126P disposed on the bottom portion of the second gate space GS2 is referred to as the second portion 126_2 of the dummy gate insulating layer.

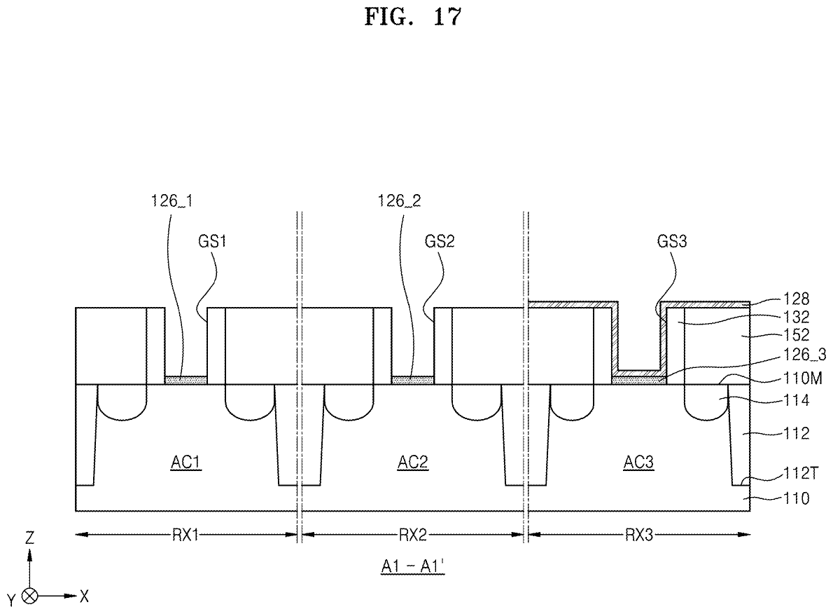

Referring to FIG. 17, the second mask M2 may be removed. After the second mask M2 is removed, the upper surface of the extra gate insulating layer 128 disposed on the third active region AC3 may be exposed. The extra gate insulating layer 128 may be disposed to extend from the inner wall of the third gate space GS3 to the upper surface of the inter-gate insulating layer 152.

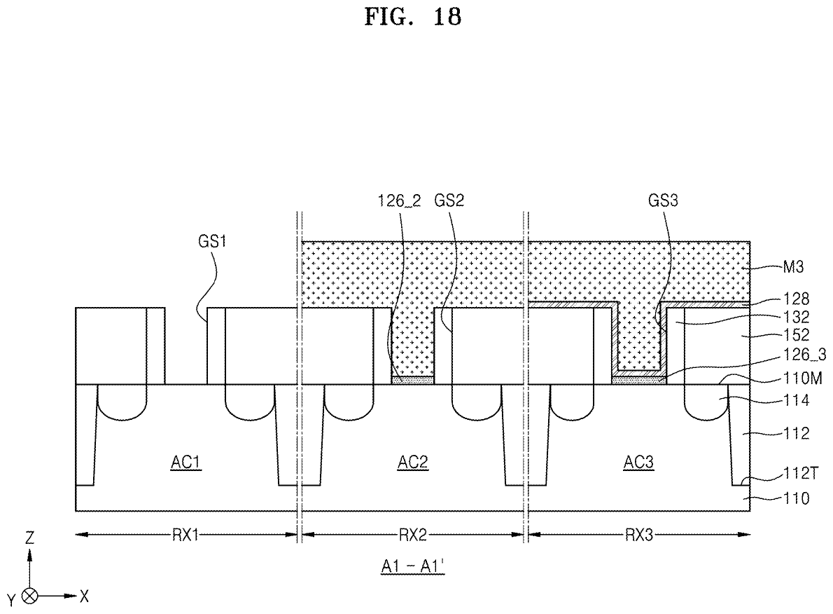

Referring to FIG. 18, a third mask M3 covering the second active region AC2 and the third active region AC3 and not covering the first active region AC1 may be formed. For example, the third mask M3 may be disposed to cover the second portion 126_2 of the dummy gate insulating layer disposed in the second active region AC2 and the extra gate insulating layer 128 disposed in the third active region AC3 and not to cover the first portion 126_1 of the dummy gate insulating layer disposed in the first active region AC1.

Thereafter, while the third mask M3 covers the second active region AC2 and the third active region AC3, the first portion 126_1 of the dummy gate insulating layer disposed in the first active region AC1 may be removed. In some embodiments, after the first portion 126_1 of the dummy gate insulating layer is removed, the upper surface 110M of the substrate 110 may be exposed to the bottom portion of the first gate space GS again.

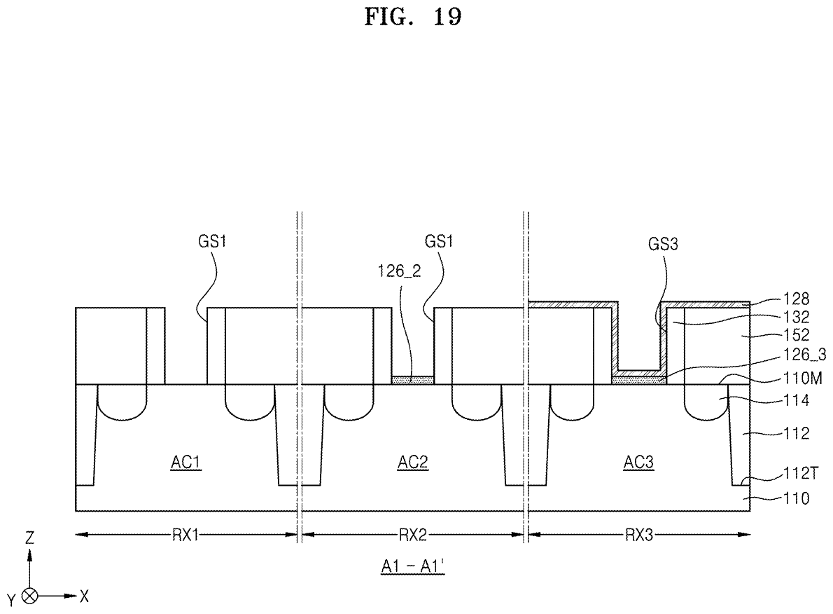

Referring to FIG. 19, the third mask M3 may be removed. After the third mask M3 is removed, the upper surface of the extra gate insulating layer 128 disposed on the third active region AC3 may be exposed. Also, the upper surface of the second portion 126_2 of the dummy gate insulating layer disposed on the second active region AC2 may be exposed again. The second portion 126_2 of the dummy gate insulating layer may be disposed to cover the upper surface 110M of the substrate 110 on the bottom portion of the first gate space GS.

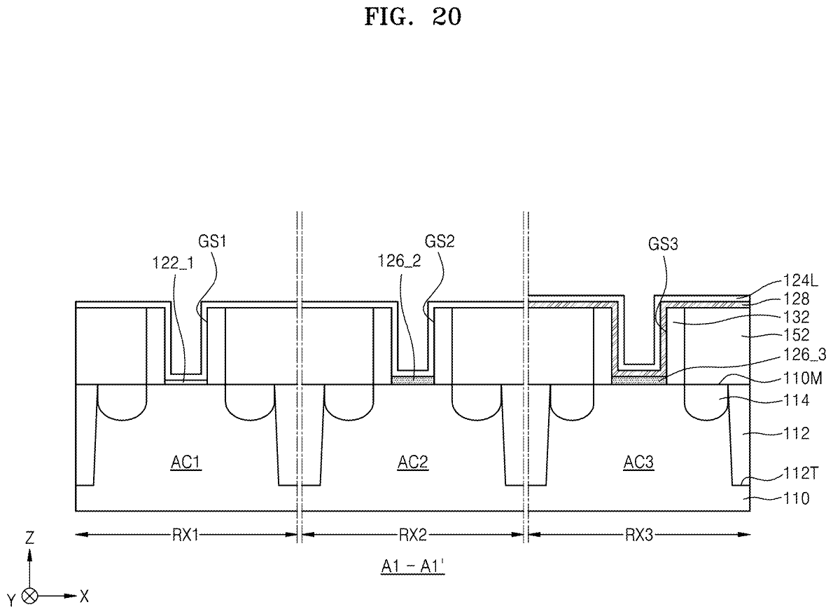

Referring to FIG. 20, the interfacial layer 122_1 may be formed on the upper surface 110M of the substrate 110 exposed to the bottom portion of the first gate space GS1.

In some embodiments, a process of forming the interfacial layer 122_1 may include a thermal oxidation process. The interfacial layer 122_1 may include a silicon oxide layer formed on the upper surface 110M of the substrate 110 by the thermal oxidation process.

Thereafter, a gate insulating layer 124L may be formed on the inner walls of the first gate space GS1, the second gate space GS2, and the third gate space GS3. The gate insulating layer 124L may be conformally formed on the inner walls of the first gate space GS1, the second gate space GS2, and the third gate space GS3 and on the upper surface of the inter-gate insulating layer 152. For example, on the first active region AC1, the gate insulating layer 124L may be formed on the sidewalls of the pair of spacers 132 in the first gate space GS1 and on the upper surface of the interfacial layer 122_1. On the second active region AC2, the gate insulating layer 124L may be formed on the sidewalls of the pair of spacers 132 in the second gate space GS2, and on the upper surface of the second portion 126_2 of the dummy gate insulating layer. On the third active region AC3, the gate insulating layer 124L may be formed on the sidewall and the upper surface of the extra gate insulating layer 128 in the third gate space GS3. The gate insulating layer 124L on the third active region AC3 may not be in direct contact with the pair of spacers 132.

In some embodiments, the gate insulating layer 124L may be formed using a high-k dielectric material, and may be formed to a thickness of about 2 angstroms to about 20 angstroms.

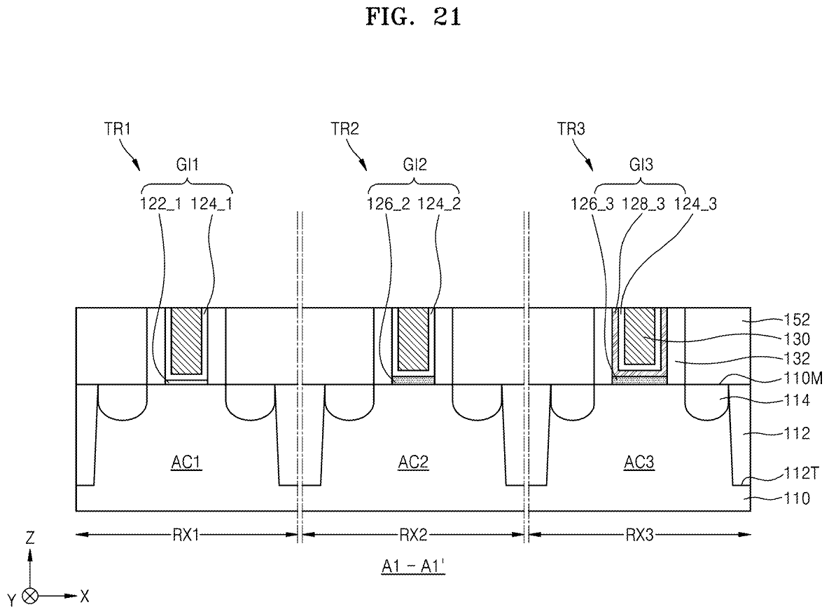

Referring to FIG. 21, the gate electrode 130 may be formed by forming a conductive layer on the gate insulating layer 124L, and removing the upper side of the conductive layer by a planarization process until the upper surface of the inter-gate insulating layer 152 is exposed. In the planarization process, a portion of the gate insulating layer 124L disposed on the upper surface of the inter-gate insulating layer 152 may also be removed. A portion of the gate insulating layer 124L disposed in the first gate space GS1 may be referred to as the first portion 124_1 of the gate insulating layer, a portion of the gate insulating layer 124L disposed in the second gate space GS2 may be referred to as the second portion 124_2 of the gate insulating layer, and a portion of the gate insulating layer 124L disposed in the third gate space GS3 may be referred to as the third portion 124_3 of the gate insulating layer.

After the planarization process, the first insulating structure GI1 and the gate electrode 130 may be disposed in the first gate space GS1, the second insulating structure GI2 and the gate electrode 130 may be disposed in the second gate space GS2, and the third insulating structure GI3 and the gate electrode 130 may be disposed in the third gate space GS3. Accordingly, the first transistor TR1 may be formed on the first active region AC1, the second transistor TR2 may be formed on the second active region AC2, and the third transistor TR2 may be formed on the third active region AC3.

Referring back to FIG. 2, the upper insulating layer 154 may be formed on the inter-gate insulating layer 152, and the first contact hole 160AH penetrating the upper insulating layer 154 and the inter-gate insulating layer 152 and exposing the upper surface of the impurity region 114 may be formed. Thereafter, the first contact 160A may be formed in the first contact hole 160AH using a conductive material. In addition, the second contact hole 160BH penetrating the inter-gate insulating layer 152 and exposing the upper surface of the gate electrode 130 may be formed. Thereafter, the second contact 160B may be formed in the second contact hole 160BH using a conductive material.

As integrated circuit devices become highly integrated and multifunctional, it is necessary to form a plurality of transistors respectively having a plurality of threshold voltages on a relatively narrow area. Because a high voltage transistor to which a high voltage is applied includes a thicker gate insulating layer than that of a low voltage transistor used in a core region, the gate insulating layer of the high voltage transistor may be formed while the low voltage transistor is covered by a mask. However, when a plurality of transistors respectively having a plurality of voltage levels (e.g., having a plurality of threshold voltages) are formed on an active region, an upper surface of the active region may be damaged by exposure to an etching atmosphere multiple times and by repeated mask formation/removal processes, etc., thereby increasing variations in the electrical characteristics of the transistors.

In contrast, according to example embodiments, the first to third insulating structures GIL GI2, and GI3 having different thicknesses may be formed using first to third masks and a combination of the dummy gate insulating layer 126L, the extra gate insulating layer 128, and the gate insulating layer 124L. Thus, damage due to exposure of the surface of the substrate 110 may be minimized in a process of forming the first to third insulating structures GIL GI2, and GI3. Accordingly, the integrated circuit device 100 may have excellent electrical performance.

By way of summation and review, embodiments provide a manufacturing method of an integrated circuit device including a plurality of transistors having different threshold voltages and optimized performance. That is, embodiments provide a manufacturing method where the sequence of using first to third masks and underlying layers/elements covered by the masks is adjusted to minimize exposure of the surface of the substrate to etching/removal processes, thereby minimizing damage to the substrate surface and enhancing electrical characteristics of the transistors formed thereon.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of manufacturing an integrated circuit device, the method comprising:
forming a dummy gate insulating layer on a first active region, a second active region, and a third active region of a substrate;
forming a first dummy gate, a second dummy gate, and a third dummy gate on the first active region, the second active region, and the third active region of the substrate, respectively;
forming an inter-gate insulating layer covering sidewalls of the first dummy gate, the second dummy gate, and the third dummy gate on the substrate;
forming a third gate space by removing the third dummy gate while the first and second dummy gates are covered by a first mask;
forming an extra gate insulating layer on a third portion of the dummy gate insulating layer exposed at a bottom portion of the third gate space;
forming a first gate space and a second gate space by removing the first dummy gate and the second dummy gate, respectively, while the third gate space is covered by a second mask;
removing a first portion of the dummy gate insulating layer exposed at a bottom portion of the first gate space, while the second gate space and the third gate space are covered by a third mask; and
sequentially forming a gate insulating layer and a gate electrode in the first gate space, the second gate space, and the third gate space.

2. The method as claimed in claim 1, further comprising, before forming the gate insulating layer, forming an interfacial layer on an upper surface of the first active region exposed by the first gate space.

3. The method as claimed in claim 2, wherein forming the gate insulating layer includes:
forming a first portion of the gate insulating layer on a sidewall of the first gate space and on the interfacial layer;
forming a second portion of the gate insulating layer on a sidewall of the second gate space and on a second portion of the dummy gate insulating layer, the second portion of the dummy gate insulating layer being on a bottom portion of the second gate space; and
forming a third portion of the gate insulating layer on the extra gate insulating layer in the third gate space.

4. The method as claimed in claim 2, wherein forming the interfacial layer is performed by a thermal oxidation process.

5. The method as claimed in claim 2, wherein:
the interfacial layer includes silicon oxide, and
the dummy gate insulating layer includes silicon oxide.

6. The method as claimed in claim 2, wherein:
the gate insulating layer includes a high-k dielectric material, and
the extra gate insulating layer includes silicon oxide or the high-k dielectric material.

7. The method as claimed in claim 2, further comprising, before forming the inter-gate insulating layer, forming a pair of first spacers, a pair of second spacers, and a pair of third spacers on opposite sidewalls of the first dummy gate, the second dummy gate, and the third dummy gate, respectively,
wherein forming the gate insulating layer includes forming a first portion of the gate insulating layer on the interfacial layer between the pair of first spacers, forming a second portion of the gate insulating layer on the second portion of the dummy gate insulating layer between the pair of second spacers, and forming a third portion of the gate insulating layer on the extra gate insulating layer between the pair of third spacers.

8. The method as claimed in claim 1, wherein:
the dummy gate insulating layer has a first thickness,
the extra gate insulating layer has a second thickness,
the gate insulating layer has a third thickness,
the first thickness is greater than or equal to the third thickness, and
the second thickness is greater than or equal to the third thickness.

9. The method as claimed in claim 8, wherein:
the first thickness of the dummy gate insulating layer is about 5 angstroms to about 60 angstroms,
the second thickness of the extra gate insulating layer is about 5 angstroms to about 120 angstroms, and
the third thickness of the gate insulating layer is about 2 angstroms to about 20 angstroms.

10. The method as claimed in claim 1, wherein:
each of the first active region, the second active region, and the third active region has a flat upper surface, and
the dummy gate insulating layer extends in a horizontal direction on an upper surface of the substrate.

11. The method as claimed in claim 10, further comprising forming a first impurity region on opposite sides of the first dummy gate in the first active region by an ion implantation process.

12. The method as claimed in claim 1, further comprising forming a first fin-type active region, a second fin-type active region, and a third fin-type active region protruding in a vertical direction from an upper surface of the substrate, respectively, by removing a part of each of the first active region, the second active region, and the third active region.

13. The method as claimed in claim 12, further comprising:
forming a first recess region by removing a part of the first fin-type active region disposed on opposite sides of the first dummy gate; and
forming a first impurity region in the first recess region by a selective epitaxy growth process.

14. The method as claimed in claim 12, further comprising, before forming the gate insulating layer, forming an interfacial layer on an upper surface and opposite sidewalls of the first fin-type active region exposed to the first gate space.

15. A method of manufacturing an integrated circuit device, the method comprising:
forming a dummy gate insulating layer on a first active region, a second active region, and a third active region of a substrate;
forming a first dummy gate, a second dummy gate, and a third dummy gate on the first active region, the second active region, and the third active region of the substrate, respectively;
forming an inter-gate insulating layer covering sidewalls of each of the first dummy gate, the second dummy gate, and the third dummy gate on the substrate;
forming a third gate space surrounded by the inter-gate insulating layer and having a bottom portion in which a third portion of the dummy gate insulating layer is disposed by removing the third dummy gate;
forming an extra gate insulating layer on the third portion of the dummy gate insulating layer in the third gate space;
forming a first gate space and a second gate space surrounded by the inter-gate insulating layer and having bottom portions in which first and second portions of the dummy gate insulating layer are respectively disposed by removing the first dummy gate and the second dummy gate;
removing the first portion of the dummy gate insulating layer in the first gate space;
forming a gate insulating layer in each of the first to third gate spaces; and
forming a gate electrode in each of the first to third gate spaces.

16. The method as claimed in claim 15, further comprising, before forming the gate insulating layer, forming an interfacial layer on an upper surface of the first active region exposed to the first gate space,
wherein forming the gate insulating layer includes forming a first portion of the gate insulating layer on a sidewall of the first gate space and on the interfacial layer, forming a second portion of the gate insulating layer on a sidewall of the second gate space and on the second portion of the dummy gate insulating layer, and forming a third portion of the gate insulating layer on the extra gate insulating layer in the third gate space.

17. The method as claimed in claim 16, wherein:
the interfacial layer includes silicon oxide,
the dummy gate insulating layer includes silicon oxide,
the gate insulating layer includes a high-k dielectric material, and
the extra gate insulating layer includes silicon oxide or a high-k dielectric material.

18. The method as claimed in claim 15, wherein:
the dummy gate insulating layer has a first thickness,
the extra gate insulating layer has a second thickness,
the gate insulating layer has a third thickness,
the first thickness is greater than or equal to the third thickness, and
the second thickness is greater than or equal to the third thickness.

19. The method as claimed in claim 15, further comprising:
forming a first fin-type active region, a second fin-type active region, and a third fin-type active region protruding in a vertical direction from an upper surface of the substrate respectively by removing a part of each of the first active region, the second active region, and the third active region;
forming a first recess region by removing a part of the first fin-type active region disposed on opposite sides of the first dummy gate; and
forming a first impurity region in the first recess region by a selective epitaxy growth process.

20. A method of manufacturing an integrated circuit device, the method comprising:
forming a dummy gate insulating layer on a first active region, a second active region, and a third active region of a substrate;
forming a first dummy gate, a second dummy gate, and a third dummy gate, respectively, on the first active region, the second active region, and the third active region of the substrate;
forming a pair of first spacers, a pair of second spacers, and a pair of third spacers on opposite sidewalls of each of the first dummy gate, the second dummy gate, and the third dummy gate, respectively;
forming an inter-gate insulating layer covering sidewalls of the pair of first spacers, the pair of second spacers, and the pair of third spacers on the substrate;
forming a first mask covering the first dummy gate and the second dummy gate and not covering the third dummy gate;
forming a third gate space defined between the pair of third spacers and having a bottom portion in which a third portion of the dummy gate insulating layer is disposed by removing the third dummy gate;
forming an extra gate insulating layer on the third portion of the dummy gate insulating layer in the third gate space;
forming a second mask covering the third gate space and not covering the first dummy gate and the second dummy gate;
forming a first gate space defined between the pair of first spacers and having a bottom portion in which a first portion of the dummy gate insulating layer is disposed and forming a second gate space defined between the pair of second spacers and having a bottom portion in which a second portion of the dummy gate insulating layer is disposed by removing the first dummy gate and the second dummy gate;
forming a third mask covering the second gate space and the third gate space and not covering the first gate space;
removing the first portion of the dummy gate insulating layer in the first gate space;
forming a gate insulating layer in each of the first gate space, the second gate space, and the third gate space; and
forming a gate electrode in each of the first gate space, the second gate space, and the third gate space.
